(19) United States
(12) Patent Application Publication
(10) Pub. No.: US 2005/0205965 A1
(43) Pub. Date: Sep. 22, 2005

(54) Semiconductor device having a fuse including an aluminum layer

(75) Inventor: Chao-Hsiang Yang, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/804,713

(22) Filed: Mar. 18, 2004

(51) Int. Cl. H01L 21/82; H01L 29/00

(52) U.S. Cl. 257/529; 438/215

(57) ABSTRACT

A semiconductor device comprising a damascene structure comprising copper and a fuse comprising aluminum connected to the damascene structure.

### FIELD OF THE INVENTION

This invention relates to semiconductor device, and more particularly to a semiconductor device having a fuse including an aluminum layer.

### BACKGROUND OF THE INVENTION

Semiconductor devices including a fuse portion and methods of blowing or trimming the fuse are known to those skilled in the art. Lee et al. U.S. Pat. No. 5,879,966 discloses a structure and method for forming a protective layer over an opening in insulation layers over a fuse. The protective layer prevents contaminants from entering the exposed insulation layers in the fuse opening while not interfering with the laser trimming of the fuse. An opening through the layers over a fuse is made forming vertical side walls which exposed portions of the insulation layers. A protective layer is formed over the insulation layers, side walls and fuse thereby preventing contaminants from diffusing into the exposed insulation layers. A second opening is made in the protective layer over the fuse to allow a laser beam to melt the underlying fuse link. The fuse can be formed out of the metal, such as platinum silicide or tantalum tungsten, or polysilicon. The fuse typically has a thickness ranging from 500-5000 angstroms and length ranging from 5-10 microns with a width in the range of 1-3 microns. The fuse can be blown by applying laser beam thereto to allow redundant circuit devices to be activated and replaces defective devices.

Yoo et al., U.S. Pat. No. 5,79,041 discloses an integrated circuit including a conductive fusible link that may be blown by heating with laser irradiation. The integrated circuit includes a silicon substrate, first insulating layer, a fusible link in the first layer, a second insulating layer overlying the first layer and the fusible link, an opening through the second layer exposing the fuse, and a protective layer over the surfaces of the opening. A laser is directed through the opening in the protective layer to melt the fusible link. The protective layer is highly transparent to the laser beam and does not interfere with the laser melting (trimming) evaporation. Further, the protective layer prevents contaminants from diffusing into the opening to harm adjacent semiconductor devices. The protective layer may be formed from plasma enhanced chemical vapor deposition silicon nitride. The laser can be a Yumium-Yag laser operated at a wavelength ranging from 1037-1057 nanometers and a pulse less than 35 ns. The fuse can be formed of a metal such as aluminum, platinum silicide, tantalum tungsten or polysilicon. Alternatively, the fuse can be formed of a polycide, such as titanium polycide, tungsten polycide, or molybdenum polycide. The fuse typically has a thickness ranging from 500-5000 angstroms and length ranging from 5-10 microns and a width in the range of 1-3 microns.

Huang et al., U.S. Pat. No. 6,121,073 discloses a fuse structure and method of deleting redundant circuit elements on a semiconductor device. The fuse structure is useful in increasing the repair yield on RAM chips by deleting defective rows of memory cells. The method involves forming a fuse area in a patterned electrical circuit layer also used to form interconnections. The fuse may be a polysilicon layer. A relative thin layer of about 0.1 micrometers of insulation is deposited having a uniform thickness across the substrate. The next level of patterned interconnections is formed with a portion of the layer aligned over the fuse area to serve as an etch-stop layer. The conducting layers can be first and second polysilicon layer on a RAM chip. The remaining multilevel of interconnections are then formed having a number of relatively thick entry-level dielectric layers interposed which can have varying thicknesses across the substrate. The fuse windows were openings are then selectively etched in the entry-level dielectric layers to the etch stop layer and the etch stop layer is selectively etched in the fuse window to the insulating layer over the fuse area. The process allows fuse structures to be built without over etching and thereby causing fuse damage. The uniformly thick insulating layer allows repeatable and reliable laser evaporation to open the desired fuses.

Ying et al., U.S. Pat. No. 6,330,252 discloses a method of etching fuse windows through a passivation layer at least two inter-metal dielectric layers that are deposited on top of the fuse when the fuse is embedded in an insulating material including a top layer of silicon nitride on a semiconductor substrate. The method can be carried out by a two-step etching processing in which an opening is first etched for the fuse window through a passivation layer by a first etchant that has low selectivity to the passivation material and then the opening is etched through the inter-metal dielectric layers in a second etching process by a second etchant which has high selectivity to the silicon nitride etch-stop layer. The two-step etching process can be easily controlled so that the quality and yield of the resulting fuse window is improved. The fuse may be polycide fuse including a polysilicon layer and a tungsten silicide layer. The fuse is typically formed to a thickness in the range of about 600-6000 angstroms, a length in the range between 6-12 microns and a width ranging between 1-5 microns. The fuse can be suitably blown by the application of laser energy from a laser source such as Yumium-Yag or Neodymium-Yag at a wavelength between about 1037 -1057 nanometers, and energy of about 1-1.5 micro-joules and a pulse between about 30-50 ns.

Tsai, U.S. Pat. No. 6,295,721 discloses a fuse structure and process for forming the same. The fuse is formed of a compound layer of aluminum and chromium. The two layers are shaped to form a strip that bridges a gap between two copper dual damascene connections. By controlling the degree of overlap between the strip and connectors, the conductance of heat from the strip into the conductors can be varied, thereby allowing control of the manner in which the fuse blows when irradiated. Since there is no copper in the fuse material, blowing the fuse does not introduce unprotected copper sources into the structure. The fuse structure includes a first layer of chromium in a thickness ranging from about 200-500 angstroms. This is followed by the deposition of aluminum over the chromium layer to a thickness of about 0.2-0.5 microns. With the two layers in place standard photolithographic techniques are used to pattern the layers to shape a strip that has a same width as the exposed dual damascene connectors of about 0.8-2 microns which it overlaps at both side edges. Tsai acknowledges that experiments have shown that there is an interaction between the aluminum and copper over time which leads eventually to less than optimum performance when used as a fuse.

Pricer et al. U.S. Pat. No. 6,335,229 discloses a structure and method of blowing the fuse includes removing an insulating layer above the fuse link and etching the fuse link. The etching includes wet etching or reactive ion etching. The removing includes ablating the insulation layer using light energy. The light energy includes a laser light or ultraviolet light. The method is particularly useful with easily corroded metals such as copper and silver, or low dielectric constant material such as polyimide nanoforms or porous glasses. The dielectric layer may be removed to expose the fuse material using conventional removal techniques such as reactive ion etching. As an alternative to etching, the dielectric layer is a low dielectric constant material that may be ablated using a laser at an appropriate wavelength, typically between 150-400 nanometers. The fuse material is etched and removed thus completing the fuse blowing process. The etching may be wet etching using a solution appropriate to the fuse material, such as a solution of ammonium persulfate if the material is copper or dry reactive ion etching using an etching gas containing boron chloride if the fuse is aluminum. A sequence of wet and dry etching may also be used. Pricer recognizes that high conductance metals such as copper or silver readily corrode if left exposed to the atmosphere. Therefore, Pricer opens the dielectric, etches the fuse and thereafter deposits oxide over the fuse window after fuse trimming. However, low dielectric material are mechanical and thermally fragile and can be damaged or collapsed under standard laser fuse blowing conditions.

FIG. 1 illustrates a prior art semiconductor device 10 including a fuse 12. A layer of field oxide 14 is provided over a silicon substrate 16 including, for example, a p-well 18. Two fragments of polysilicon wiring 20, 22 are connected to two electrically separate devices but in a fuse arrangement, each being upwardly connected to five levels of dual damascene structures 24, 26 that are embedded in dielectric 28. They share a common trench (or stripe) portion 12 at their topmost level. The shared topmost level 12 of damascene wiring can be used as a fuse. In order to make the connecting copper stripe fusible under the influence of external radiation, most dielectric material directly above the stripe is etched away to form a fuse cavity. A relatively small thickness of approximately 500-4000 angstroms of dielectric 32 is left in place. This residual layer 32 is thick enough to passivate the copper while at the same time being thin enough to allow the laser beam to pass through with minimal attenuation as well as being thin enough to disintegrate when the fuse is blown. There are several problems associated with this method of making a fusible connection with any copper damascene device. Because the topmost metal layer is relatively thick and is copper which is a good thermal conductor and because it has relatively high melting point, the energy needed to fuse the copper is relatively high on the range of 1.0-2.0 micro-joules energy. This makes a copper fuse incompatible with existing laser trimming techniques that were developed prior to the extensive use of copper damascene in the semiconductor industry. Furthermore, additional problems are associated with copper fuses because of the low dielectric material surrounding the copper. Low dielectric oxide is fragile and easy to crack in a laser process. Reliability becomes an issue when using copper fuses in a low dielectric material environment. The laser trimming process performed on the low dielectric material includes film delamination and crack after stressing in a reliability testing environment. As shown in FIG. 1, a guard ring 34 is provided. This is a series of dummy dual damascene structures that form a ring completely surrounding a fuse cavity 30. The purpose is to terminate the promulgation of cracks in the dielectric 28 that may appear after the fuse 12 has been blown. While micro cracks will propagate relatively easily through the hard and brittle dielectric 28, the cracks are stopped by the soft metal of the guard ring 34.

The present invention provides alternatives to, and/or advantages over the prior art.

### SUMMARY OF THE INVENTION

One embodiment of the invention includes a semiconductor device comprising a damascene structure comprising an interconnected metallization structure comprising copper and a low dielectric material surrounding the structure, and a fuse comprising aluminum connected to the structure.

Another embodiment of the invention includes a semiconductor device including a damascene structure and a fuse comprising a first layer comprising copper islands and a second layer overlying the copper islands, and wherein the second layer comprises aluminum.

Another embodiment of the invention method of blowing a fuse in a semiconductor device including at lest a first metallization layer comprising copper and a fuse connected to the first metallization layer, and wherein the fuse comprises aluminum, comprising: directing a laser beam onto the fuse using a wavelength ranging from 300-500 or 1000-1400 nm.

These and other embodiments of the present invention will become apparent from the following brief description of the drawings, detailed description of the preferred embodiments, and appended claims and drawings.

### BRIEF DESCRIPTION OF THE DRAWINGS

FIG. 1 illustrates a prior art semiconductor device having a fuse.

FIG. 2 illustrates a semiconductor device having a fuse according to the present invention.

FIG. 3 illustrates an alternative embodiment of a semiconductor device having a fuse according to the present invention.

### DETAILED DESCRIPTION OF THE PREFERRED EMBODIMENTS

FIG. 2 illustrates a semiconductor device 50 with portions broken away according to the present invention. The semiconductor device 50 may include a base portion (not shown) with discrete devices formed therein. The semiconductor device 50 may also includes an oxide or low dielectric material 52 including a number of discrete semiconductor structures (not shown) formed therein. A multilayer structure may be formed over the oxide or low dielectric material 52 including a plurality of dielectric layers 56 which may be silicon dioxide, or may be a low dielectric material such as polyimide nanoforms or porous glasses. An etch-stop layer 54 such as silicon nitride may be positioned between adjacent layers of dielectric material. A damascene structure 58 is provided in the dielectric material and includes at least a first (first from the topmost metallization layer) metallization layer 60, a plug 62 and a topmost (second) metallization layer 64 which may be the top metallization layer. The top metallization layer 62 may have a thickness of about 9000 angstroms or more. A fuse 66 is formed on the topmost metallization layer 64. Preferably the fuse is aluminum material formed at a thickness of about 1000-7000 angstroms and preferably 3500 angstroms. The fuse may be formed by an additional masking step using a patterned photoresist layer with an opening therein through which the aluminum may be deposited on top of the top metallization layer 64 by electroplating, screening or other methods known to those skilled in the art. An additional passivation layer 68 may be provided over the multilayer structures and may be a single layer or a layer of plasma enhanced silicon nitride to a thickness of about 750 angstroms and a layer of plasma enhanced oxide to a thickness of about 4000 angstroms. Additional passivation layers 72, 74 may also be provided and may be a layer of plasma enhanced oxide to a thickness of about 4000 angstroms and layer of plasma enhanced silicon nitride to a thickness of about 6000 angstroms. A fuse window 76 is provided through the passivation layers down to the fuse passivation layer 68. The fuse 66 may be blown by energizing the fuse with a laser through the fuse passivation layer 68. Preferably when the dielectric layers 52, 56 are a low dielectric material, a laser beam is utilized to blow the fuse. The low dielectric material layers 52, 56 may have a dielectric constant k ranging from 2.0-3.6 and preferably from 2.2-3.0 . The combination of a low dielectric and a tick top metal layer such as a copper damascene structure with a low-k dielectric increases the chance of having lower corner cracks and copper fuse residue due to the low-k dielectric softness. Lower corner cracking may produce unclean link removal and damage to the circuit. Consequently, metal links are cut more effectively at lower nominal energies and less likely to have lower corner cracking beneath the fuse link.

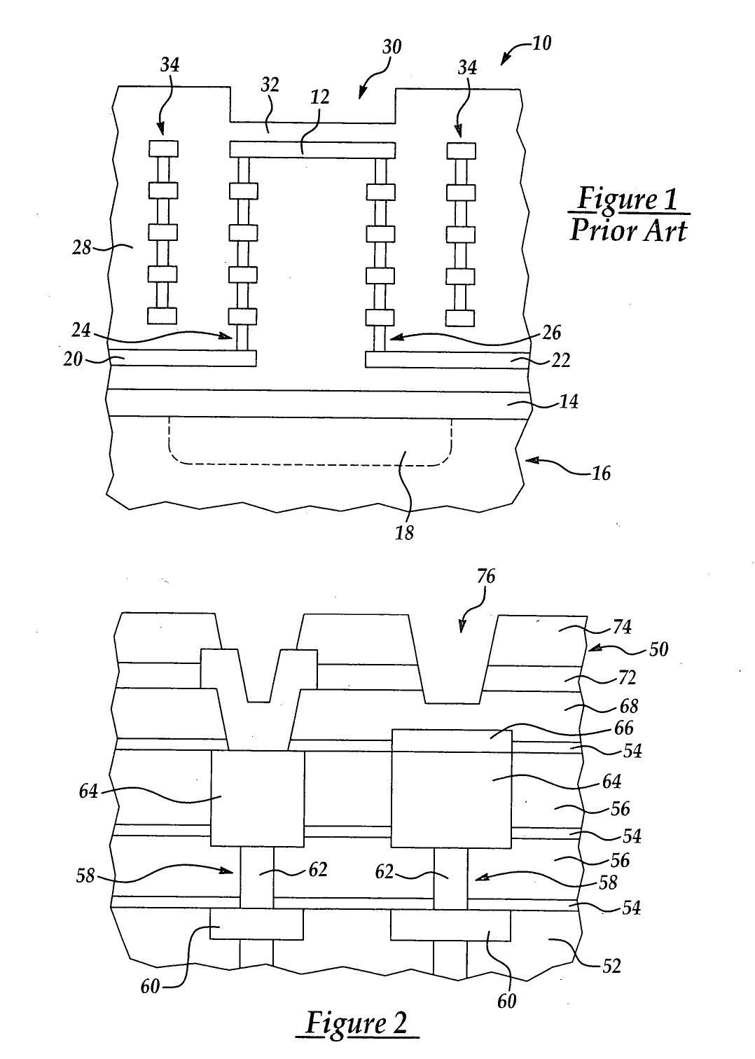

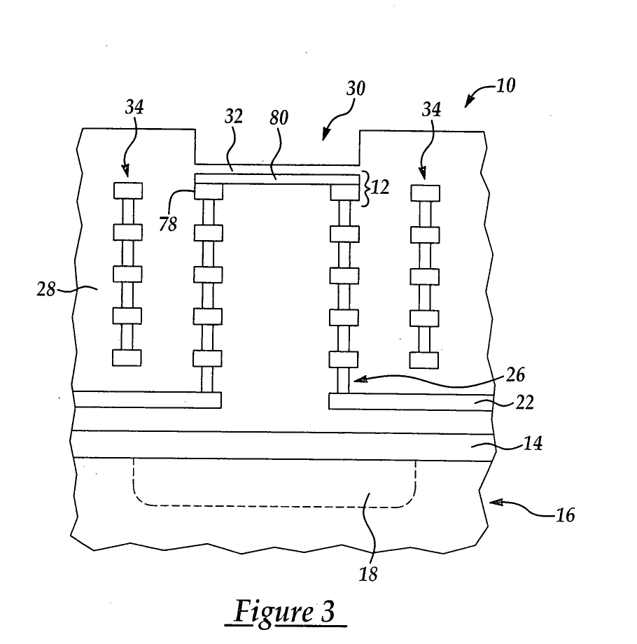

FIG. 3 illustrates a semiconductor device 10 having a fuse 12 according to the present invention. The structure shown in FIG. 3 is similar to the prior art structure shown in FIG. 1 with the exception that the fuse 12 includes a first layer 78 of copper and a second layer 80 of aluminum. Again, a thin layer of dielectric 32 overlies the fuse 12. The use of the aluminum layer 80 reduces the chance of the copper from forming oxides after the fuse is blown.

1. A semiconductor device comprising:
a substrate;
a top inter-metal dielectric layer on said substrate;
at least two top metal lines in said top inter-metal dielectric layer;
a fuse on said top inter-metal dielectric layer, said fuse in electrical communication with at least one of said at least two top metal lines; and
a protective layer on said fuse.

2. A semiconductor device according to claim 1, wherein said protective layer on said fuse comprises a dielectric layer.

3. A semiconductor device according to claim 2, wherein said dielectric layer comprises silicon dioxide.

4. A semiconductor device according to claim 1, wherein said fuse comprises an aluminum fuse.

5. A semiconductor device according to claim 1, wherein said at least two top metal lines comprises copper.

6. A semiconductor device comprising an interconnected metallization structure comprising copper and a low dielectric material surrounding the structure, and a fuse comprising aluminum connected to the structure.

7. The semiconductor device as set forth in claim 6 further comprising a dielectric layer overlying the fuse.

8. The semiconductor device as set forth in claim 7 wherein the dielectric layer comprises silicon dioxide.

9. The semiconductor device as set forth in claim 6 wherein the structure includes a first metal layer and a topmost metal layer and further comprising an inter-metal dielectric layer comprising a low dielectric constant material interposed between the first metal layer and a second metal layer of the structure.

10. The semiconductor device as set forth in claim 9 further comprising an etch stop layer on each of face of the inter-metal dielectric layer.

11. The semiconductor device as set forth in claim 9 further comprising a plug extending between the first metal layer and the topmost metal layer of the structure.

12. The semiconductor device as set forth in claim 6 wherein the aluminum fuse has a thickness ranging from 1000-7000 angstroms.

13. The semiconductor device as set forth in claim 9 wherein the topmost metal layer of the structure has a thickness of at least 8000 angstroms.

14. A semiconductor device including a fuse comprising a first layer comprising a copper island and a second layer overlying the first layer, and wherein the second layer comprises aluminum.

15. The semiconductor device as set forth in claim 14 further comprising a dielectric layer overlying the fuse.

16. The semiconductor device as set forth in claim 15 wherein the dielectric layer comprises silicon dioxide.

17. The semiconductor device as set forth in claim 14 further includes a first metal layer and a topmost metal layer and further comprising an inter-metal dielectric layer comprising a low dielectric material interposed between the first metal layer and the topmost metal layer.

18. The semiconductor device as set forth in claim 17 further comprising an etch stop layer on each face of the inter-metal dielectric layer.

19. The semiconductor device as set forth in claim 17 further comprising a first passivation layer overlying the topmost metal layer.

20. The semiconductor device as set forth in claim 17 further comprising a plug extending among each second metal layer.

21. A semiconductor device as set forth in claim 19 further comprising a fuse window formed through the passivation layer down to the fuse passivation layer overlying the fuse.

22. A method of blowing a fuse in a semiconductor device including at lest a first metallization layer comprising copper and a fuse connected to the first metallization layer, and wherein the fuse comprises aluminum, comprising: directing a laser beam onto the fuse using a wavelength ranging from 300-500 or 1000-1400 nm.

23. The method as set forth in claim 22 wherein the semiconductor device further includes a fuse passivation layer overlying the fuse.

24. The method as set forth in claim 22 wherein the fuse passivation layer comprises silicon dioxide.

25. The method as set forth in claim 22 wherein the fuse comprises a first layer comprising aluminum.

26. The method as set forth in claim 22 wherein the fuse comprises a first layer comprising a copper island and a second layer comprising aluminum.

27. The method of blowing a fuse in a semiconductor device including at least a first metallization layer comprising copper and a fuse connected to the first metallization layer, and wherein the fuse comprises aluminum, comprising: directing a laser beam onto the fuse using a wavelength ranging from 300-500 or 1000-1400 nm.
